(19) United States
(12) Patent Application Publication
(10) Pub. No.: US 2004/0104857 A1
(43) Pub. Date: Jun. 3, 2004

(54) Method for testing a measurement recording device and corresponding testing device

(76) Inventor: Rolf Kaindl, Freising (DE)

Correspondence Address: EDELL, SHAPIRO, FINNAN & LYTLE, LLC, 1901 RESEARCH BOULEVARD, SUITE 400, ROCKVILLE, MD, 20850, US

(21) Appl. No.: 10/468,410

(22) PCT Filed: Mar. 1, 2002
(86) PCT No.: PCT/DE02/00742

(30) Foreign Application Priority Data
Mar. 2, 2001 (DE) 101 10 207.0

(51) Int. Cl. G01R 1/00

(52) U.S. Cl. 343/703; 324/76.14

(57) ABSTRACT

The invention relates to a method for testing a measurement recording device (3) that, in a first test operating mode for testing radio devices (10), is coupled, on the one hand, to a testing device (1) for testing the radio devices and, on the other hand, to a radio device. The method makes it possible to test a measurement recording device (3) for mobile telephones in a real production environment without interrupting the production process. To this end, a second test operating mode for testing the measurement recording device (3) is provided, in which the measurement recording device (3) is coupled, on the one hand, to the testing device (1) for testing the radio devices and, on the other hand, to an essentially defined terminating impedance (17), whereby the measurement recording device (3) is tested by the testing device (1) provided for testing radio devices. The invention also relates to a testing device (1) for testing radio devices and to the use thereof.

The present invention relates to a method for testing a measurement recording or performing device which, in a first test operating mode for testing radio devices, is coupled or can be coupled firstly to a test device for testing the radio devices and secondly to a radio device. The present invention also relates to a test device for testing radio devices such as mobile telephones which are intended to be operated in a mobile radio network, which is coupled or can be coupled to the radio devices via a measurement recording device in a first test operating mode for testing radio devices. The present invention finally relates to the use of a test device for testing radio devices for testing a measurement recording device, which is coupled to it, by means of an impedance measurement.

Test devices for testing mobile telephones are known from the prior art. Test devices such as these are used in particular in production workshops and service centers in order to test mobile telephones for compliance with the specifications required for operation. In a known application, all possible types of mobile telephones or cellular phones are tested with the aid of specific measurement recording devices and test adapters for discrepancies from the required specifications. As a result of the test, damaged mobile telephones are segregated and are repaired. The specifications to be complied with by mobile telephones are in this case so tight that even small measurement errors in the order of magnitude of a few tenths of one dB are problematic. In production, measurement recording devices such as these have a high throughput rate of several thousand mobile telephones per day and are thus subjected to high loads, in particular mechanical loads. The mobile telephones are, for example, pushed into the measurement sensor and removed from it pneumatically. Even minor discrepancies in contact resistances, such as those caused by dirt for example, or in the electrical characteristics of switches or cables (loose connections, pinches etc.) lead to discrepancies in the measurement results, and thus to a reduction in the production yield and to adjustment measures which are carried out in response to an incorrect test result. The known measurement recording devices which are used, in particular, in the production of mobile telephones thus have a major influence on the accuracy of measurements and hence on what is referred to as the yield or production yield. The quality of the measurement recording devices has to be checked from time to time, particularly owing to the high mechanical loads.

It is now known from the prior art for tests for the measurement recording devices or test adapters to be carried out “removed” from the production arrangement by means of what is referred to as a four-pole test rig in a phase during which the test operation for the radio devices is interrupted. A four-pole test rig such as this is not only highly expensive, but also requires appropriate adaptations in order to be adapted for testing a measurement recording device. The complex test layout which is required for this purpose also does not allow regular inspection measurements during production, since production must be interrupted in order to check the quality. This not only involves a large amount of effort but also interferes with the production process, thus resulting in unacceptable production losses. The necessity to interrupt production means that the measurement recording device is tested only when the probability of degradation of the measurement recording device is sufficiently high. However, this in turn means that, in some circumstances, a large number of mobile telephones will have been tested incorrectly, or will have been adjusted incorrectly.

The object of the present invention is thus to avoid the disadvantages of the prior art and, in particular, to specify a method by means of which a measurement recording device for mobile telephones can be tested in an actual production environment, without interrupting the production process.

In one method of the type mentioned initially, the object according to the invention is achieved in that a second test operating mode for testing the measurement recording device is provided, in which the measurement recording device is coupled firstly to the test device for testing the radio devices and secondly to a defined or an essentially defined terminating impedance, with the measurement recording device being tested by the test device for testing radio devices.

One particular advantage of the present invention is that the testing is not carried out by a separate appliance with a high degree of technical complexity but using a test device or radio test rig which is provided in any case, even if for a different purpose, namely for testing the mobile telephones.

A further advantage of the present invention is that the test method according to the invention can be carried out completely automatically, that is to say without any involvement by operating personnel, so that there is only a minimal adverse effect on the production process, and additional capacity is created for operating personnel.

Finally, a further advantage of the present invention is that the test method according to the invention can be carried out continually, for example at regular time intervals, and in particular sufficiently quickly that only a minimal level of intervention is required in existing production processes.

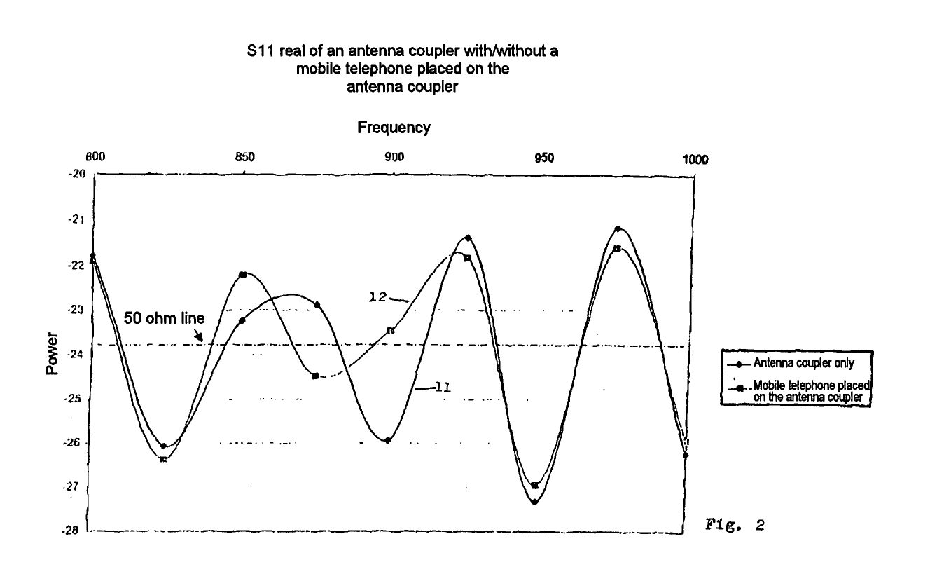

The impedance of the measurement recording device, preferably the real part of the impedance, is preferably recorded as a function of the frequency by the test device in order to test the measurement recording device. Experiments have shown, in this context also see FIGS. 2 to 5 which are attached to the application, that the profile of the impedance of the measurement recording device as a function of frequency is ideally suited for detection of degradations in the measurement recording device which are relevant for measurement purposes. A reflection measurement is particularly preferable, in which the power is measured and which is essentially influenced by the real part of the impedance of the measurement recording device. A power measurement is also preferable, in particular, because such a power meter is already integrated in an actual test device for testing mobile telephones. The second test operating mode according to the invention can in this case be carried out at a single frequency, at two or more discrete frequencies, or else over a frequency band.

The test device for testing radio devices advantageously has signal generator means and receiving means which are connected to one another via a single I/O connection, with the measurement recording device being connected to the I/O connection, and with at least one signal which is produced by the signal generator means in the second test operating mode being received by the receiving means and then compared with at least one previously stored reference value. This results in particular in a relative measurement in the second test operating mode. In plain words, this allows an electrical “fingerprint” of the measurement recording device to be recorded in the second test operating mode, and allows this to be checked for any change or constancy in subsequent measurements.

The frequencies of the signal generator means and of the receiving means are preferably tuned synchronously over a predetermined frequency range in the second test operating mode. The synchronous frequency tuning of the signal generator means and receiving means results in optimum measurement sensitivity of the second test operating mode according to the invention.

A variant of the invention which is preferable for measurement purposes provides for the predetermined frequency range to have at least one operating frequency range of a radio device. The use of test frequencies in at least one operating frequency range of the radio device on the one hand ensures that a sufficiently large number of frequencies are used which are suitable for definition of a “fingerprint” of the measurement recording device. Furthermore, the measurement recording device is generally designed such that few disturbance effects, such as resonances or the like, normally occur at the operating frequencies of the radio device. Finally, this is also preferable since the test device for testing the mobile telephones is optimized for such frequency ranges, and adverse effects in the measurement recording device have a particularly disadvantageous effect on the functional testing of the mobile telephones in these frequency ranges.

The frequency tuning is preferably carried out in steps. Frequency tuning in steps has the advantage that this allows the signal generator means and the receiving means to be tuned synchronously in a simple and quick manner. Furthermore, the entire frequency range can be covered in a simple manner in this way.

In order to simplify the evaluation of the signals, it is preferable for the level of the signals which are produced by the signal generator means to be constant during the frequency tuning. The provision of a constant level sufficiently simplifies the evaluation of the signals which are received in the power meter.

A measurement curve recorded over the frequency range is preferably compared with a reference curve. This makes it possible to use an optimum characteristic of the measurement recording device. The reference curve is in this case preferably a curve which was recorded when it was certain that the measurement recording device was operating correctly. As an alternative to this, the reference curve can also be a theoretically determined curve. Finally, it is feasible for the reference curve to have components which are determined by measurement and components which are determined theoretically.

In order to carry out the measurement of the measurement recording device repeatedly and to integrate this in the test mode for the radio devices, it is preferable for the second test mode to be carried out intermittently with respect to the first test mode.

Since the measurement method according to the invention takes less than one second, it is preferable to interrupt the first test mode once or particularly more, with the test according to the invention of the measurement recording device in the second test operating mode being carried out during this interruption, once a test of a mobile telephone in the first operating mode has been completed. This ensures in particular that any degradation of the measurement recording device while the test is being carried out is identified with sufficiently high confidence.

The measurement recording device advantageously comprises the terminating impedance. In this case, it is preferable for the terminating impedance to be an antenna coupler. In the situation where the measurement recording device itself has a reproducible terminating impedance, the method according to the invention can be carried out particularly easily. The second test operating mode according to the invention can be used for testing the measurement recording device without having to carry out any further measures.

It is likewise preferable for the terminating impedance to be a test radio device. In this case, the test radio device is preferably an unequipped mobile telephone which has an equivalent load or an equivalent terminating impedance for a coaxial connection for the measurement recording device and a mobile telephone to be tested. This exemplary embodiment is particularly preferable when the measurement recording device, as it is used in the course of a production line by way of example, does not have a sufficient reproducible terminating impedance in order to satisfactorily carry out the second test operating mode according to the invention. In this case, it is preferable for the measurement recording device to be provided with such a sufficiently reproducible terminating impedance, which is preferably a test radio device, in order to take account of the special features in the course of a production line. There is then no need to adapt the production line in order to use the second test operating mode.

For practical implementation of this exemplary embodiment, it is preferable for the test radio device to be fed into a production line or test line two or more times, with means being provided in order to identify the test radio device as such, and in order to initiate the second test operating mode in response to this.

An alarm is advantageously triggered if there is a sufficient discrepancy between the signals received by the receiving means from the reference curves. An alarm such as this may simply be an indication on the test device, which indicates to an operator the quality of the measurement recording device and, in particular, the fact that the quality is no longer adequate. The alarm device may likewise be somewhat more complex and, for example, transmit a signal in order to cause the operator to initiate necessary repair measures. The alarm may be indicated in the surrounding area by the illumination of a lamp, for example, although other options are also feasible, such as signaling by radio to an appropriate portable appliance which is carried by an operator. Finally, the discrepancy between a recording signal and the nominal or reference curve can also be used to automatically recalibrate automatically adjustable components in the measurement recording device thus resulting not only in an automatic test but also “automatic adjustment”.

The reference or a reference curve is preferably stored in a memory device which is provided in the test set or in an external appliance which is connected to it, for example a computer.

According to a further aspect, the object of the present invention is achieved by a test set for testing radio devices which is coupled to the radio devices via a measurement recording device in a first test operating mode for testing radio devices, with the test set having a second test operating mode for testing the measurement recording device, in which the measurement recording device is firstly coupled to the test device for testing the radio devices and secondly to an essentially defined terminating impedance, with the measuring recording device being tested by the test device for testing radio devices.

Finally, the object of the present invention is likewise achieved by use of a test set for testing radio devices for testing a measurement recording device, which is coupled to it, by means of an impedance measurement.

The invention as well as further features, advantages, aims and application options of the invention will be explained in more detail in the following text by means of a description of preferred embodiments. In this case, all the features which are described and/or illustrated in figures on their own or in any sensible combination form the subject matter of the present invention, to be precise irrespective of how they are summarized in the claims and in the references back to them. Throughout the drawings, the same reference symbols denote the same or corresponding elements. In the drawings:

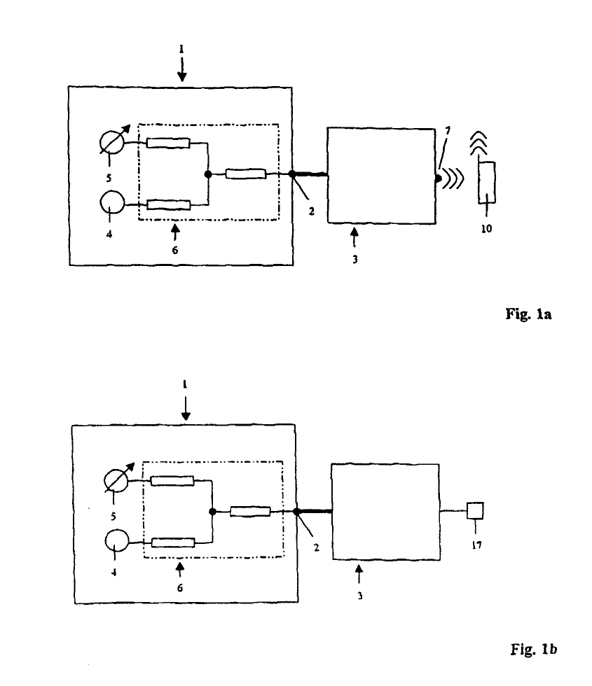

FIG. 1a shows a schematic arrangement comprising a test device for testing mobile telephones and a measurement recording device, in order to explain a first exemplary embodiment of the method according to the invention with a terminating impedance belonging to the measurement recording device;

FIG. 1b shows a schematic arrangement comprising a test device for testing mobile telephones and a measurement recording device, in order to explain a second exemplary embodiment of the method according to the invention with a separately provided terminating impedance for the measurement recording device;

FIG. 2 shows a measurement curve which was recorded using the method according to the invention and which shows the “S11 real” component of the impedance of an antenna coupler with and without a mobile telephone on the holder;

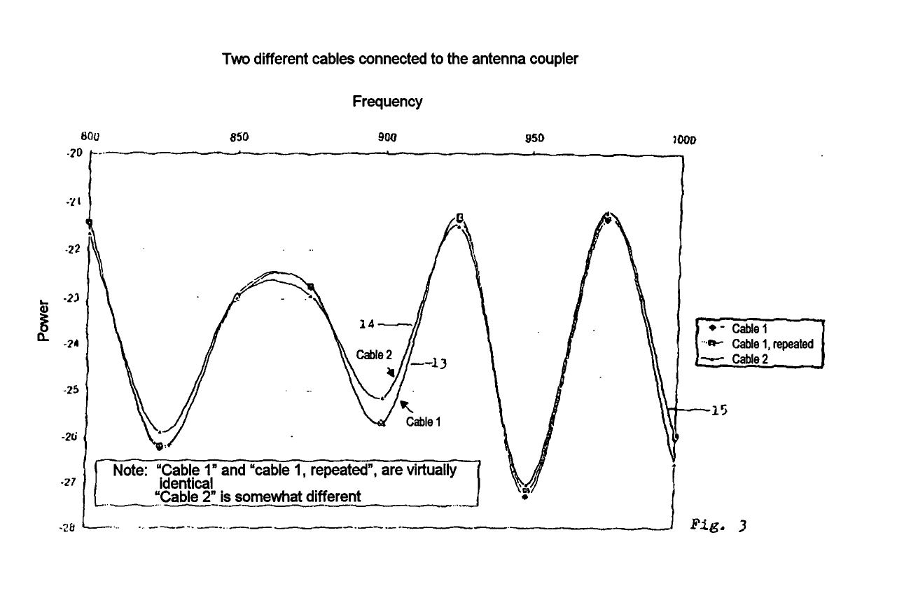

FIG. 3 shows a curve, comparable to that in FIG. 2, but for the situation in which two different cables are connected to the antenna coupler; and

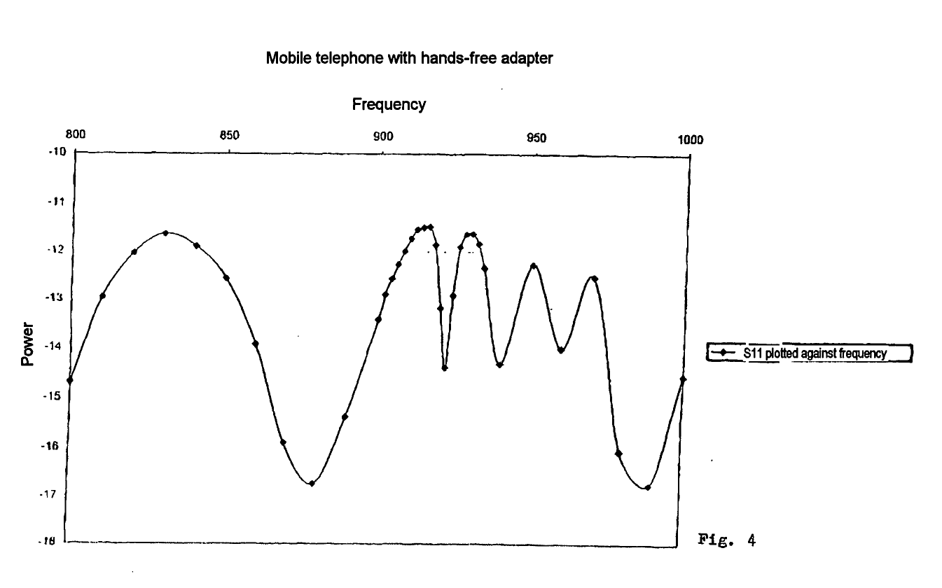

FIG. 4 shows a curve, corresponding to that shown in FIGS. 2 and 3, using a GSM mobile telephone in its commercially available hands-free adapter.

A first exemplary embodiment of the present invention will be explained in more detail in the following text with reference to FIG. 1a. FIG. 1a shows a test device for testing radio devices such as mobile telephones which are intended to be operated in a mobile radio network, and what is referred to as a radio test rig 1, illustrated schematically. The radio test rig 1 has an I/O connection 2 to which a measurement recording device or a test adapter device 3 is connected, for example, via a coaxial cable.

According to the present invention, this coaxial cable would then be associated with the measurement recording device. The radio test rig 1 is connected via the measurement recording device 3 to a mobile telephone 10 in a first test operating mode for testing the specifications of this mobile telephone 10. The mobile telephones 10 are, for example, in each case newly delivered by a conveyor belt (not shown) in a production workshop. The connection between the measurement recording device 3 and the mobile telephone 10 may be provided via an antenna coupler, that is to say via the air interface, or via a coaxial connection. In the first exemplary embodiment of the present invention, it is assumed that the measurement recording device already has a sufficiently reproducible terminating impedance. This is the case, for example, when the mobile telephone 10 is connected to the measurement recording device 3 via an antenna coupler. In this case, the measurement recording device 3 has a terminating impedance in the form of an antenna 7. With regard to the terminology, it should be noted that the measurement recording device 3 includes all the components, in particular such as cables, switches and contacts, as well as the antenna coupler, which are connected between the I/O connection 2 of the radio test rig 1 and the mobile telephone 10 to be tested, during the test mode. The measurement recording device 3 can thus be constructed such that it is very simple and may, for example, have only one cable or one connector. The measurement recording device can likewise be formed from a large number of different components. The radio test rig 1 has a signal generator means 4, in particular a tunable-frequency HF generator, and a receiving means 5, in particular a selective power meter. The HF generator 4 and the power meter 5 are connected to the I/O connection 2 via a Z/3 star 6. In order to test the measurement recording device 3, the HF generator 4 and the power meter or receiver 5 in the radio test rig 1 are internally set to the same frequency. In the test mode for the measurement recording device 3, that is to say in the second test operating mode, it is preferable for no mobile telephone 10 to be coupled to the measurement recording device 3 (in contrast to the illustration in the drawing). This has the advantage that the mobile telephone does not adversely influence the measurement of the measurement recording device 3. A corresponding power level of the HF generator 4 is measured by the power meter 5 via the Z/3 star 6 of the radio test rig 3. A measurement such as this is very precise and has an accuracy of approximately ±0.2 dB. From the point of view of the radio test rig 1, the measurement recording device 3 represents an arbitrary load, that is to say a complex impedance which influences the power level of the internal HF generator 4, as measured by the power meter 5. To be more precise, the preferred power measurement measures only the real part S11 of the impedance of the measurement recording device. For test purposes, a reference recording of an individual test layout, that is to say of an actual measurement recording device 3, is now produced with any desired number of complex components, which has a quite specific typical profile of the amplitude when plotted against the frequency. This reference recording is produced by synchronously tuning the HF generator 4 and the power meter 5 in steps. A respectively associated power level is measured by the receiver 5 and is stored. The level of the HF generator 4 is kept constant during this process. The family of curves obtained in this way is stored as a reference curve for this individual and actual measurement layout in the radio test rig 1 or in a personal computer connected to it. Subsequent control measurements, which are obtained in particular during the course of the test mode for the mobile telephones, that is to say with mobile telephones connected to the measurement recording device 3, are compared with this stored reference. This allows a relative measurement method being provided, in which even very minor discrepancies in the measurement arrangement, such as those which are caused by dirt or by changes to the electrical characteristics of switches and cables, are reproducible and can be recorded accurately. The measurement method according to the invention can be carried out completely automatically and in less than one second, and can thus be used without any restrictions, as required. The test result can be assessed as a function of a criterion which indicates the discrepancy between the recorded actual measured value curve and the desired or reference measured value curve, and any required measures can be initiated in response to this. These may be, for example, repairing of the measurement recording device 3, or replacement of components. The result of the test measurement may likewise show that the measurement recording device is fully serviceable. Various mathematical methods in order to assess the discrepancy between the two curves are suitable for the present invention. For example, the absolute magnitude of the difference function between the nominal curve and the actual curve can be integrated for this purpose. However, it is also likewise feasible to provide a threshold value for the minimum discrepancy for all the frequencies, or for specific predetermined frequencies.

A second exemplary embodiment of the present invention will now be explained in more detail in the following text with reference to FIG. 1b. In contrast to the first exemplary embodiment of the present invention which has already been described, the measurement recording device itself does not have sufficiently reproducible terminating impedance for this purpose, so that this must be provided externally. This is thus not done by using an antenna coupler. A large number of actual measurement arrangements use, for example, a direct coaxial HF connection between the measurement recording device 3 and the mobile telephone 10. The method as explained above according to the first exemplary embodiment cannot be used in this situation, since the measurement arrangement, that is to say the measurement recording device 3 has an “open” end, which means that the measurement result is largely governed only by this extreme mismatch termination. All other lesser influences of the measurement arrangement on the measurement result whose recordings are the actual aim of the check are in this case concealed. Thus, in the second exemplary embodiment of the present invention, the measurement recording device 3 is, in contrast to the first test operating mode, provided on the output side (the radio test rig 1 is connected on the input side to the measurement recording device 3) with a separate, reproducible terminating impedance 17. This terminating impedance 17 corresponds approximately to the terminating impedance of a mobile telephone. This means that it is possible to reproduce the discrepancies to be measured in the measurement recording device 3 as caused, for example, by undesirable dirt or changes to the electrical characteristics of switches and cables, and to record them without them being concealed by other effects. For terminology purposes, the expression measurement recording device 3 in the present second exemplary embodiment of the present invention refers to the entire measurement layout beyond the I/O connection 2, but without the necessary terminating impedance.

The terminating impedance 17 defined here may, for example, be applied either automatically or manually simply for test purposes to the coaxial connection at the location of a mobile telephone to be tested. However, a special method for providing a terminating impedance 17 is preferably proposed. In this embodiment of the present invention, a specific “dummy” mobile telephone is fed into the course of the test or production line. This test mobile telephone, which is provided for the purposes of testing the measurement recording device 3, is mechanically completely identical to the actual mobile telephone to be tested, so that no further changes are required in the production line. However, the test mobile telephone is an unequipped standard mobile telephone or an unequipped mobile telephone board, which is just provided with an equivalent impedance for the coaxial antenna connection. In this case, the accuracy of this equivalent impedance is irrelevant, within wide limits. It must only be sufficiently accurately reproducible and this can be ensured, in particular, by always using the same test mobile telephone for the reference and control measurements. A “dummy” mobile telephone such as this can reliably be detected at any time during the course of the production test program on the basis of parameter measurements which relate, for example, to the current draw, and can be branched off in a corresponding fully automatic way for checking the measurement arrangement.

In order to explain the method according to the invention, particularly with regard to its insensitivity, FIG. 2 shows the “S11 real” curve profile (measured power plotted against frequency) for an antenna coupler, by way of example such as that from German Patent 197 32 639 whose owner is the applicant for the present patent application, subject to two conditions. In this case, a first curve 11 relates to a first measurement in which no mobile telephone is provided on the holder of the antenna coupler. A further curve 12 shows the profile of the power as measured by the power meter 5 as a function of the frequency in the situation in which a mobile telephone is provided on the holder of the antenna coupler. The illustration in FIG. 2 shows that there are particular discrepancies in the operating frequency range of the mobile telephone. However, the discrepancies between the two curves are also so sufficiently severely pronounced in the other frequency ranges that the change in the measurement situation is identified (antenna coupler with/without a mobile telephone placed in the holder).

FIG. 3 shows a further recorded measurement curve, illustrating a measurement curve (power plotted against frequency) obtained using the present invention. The curves 13 and 14 show the measurement result by using an antenna coupler with two externally identical, industrially manufactured, high-quality cables. Although the two curves are identical over wide regions of the recorded frequency range, there is a considerable discrepancy, however, for example at a frequency of about 900 MHz. FIG. 3 likewise shows a curve 15 which in general corresponds to the curve 13, and in which a measurement is shown with the same cable, but carried out as a repeat measurement after several days.

Finally, FIG. 3 shows the “S11 real” curve profile for a GSM mobile telephone in its commercially available hands-free adapter. The profile of this curve indirectly also shows the quality of the matching of the antenna input of the mobile telephone in the transmission frequency range of the GSM mobile telephone. Repeated measurements showed that slight “tilting” of the mobile telephone in the holder can easily be identified, since the curve illustrated in FIG. 5 then changes considerably. The method according to the invention can thus also be used for identifying good coupling between the mobile telephone and the measurement recording device during a functional test.

The invention has been explained in relatively great detail above with reference to the preferred exemplary embodiments. However, it is obvious to those skilled in the art that various modifications and changes can be made without departing from the idea on which the invention is based.

1. A method for testing a measurement recording device (3) which, in a first test operating mode for testing radio devices, is coupled firstly to a test device (1) for testing the radio devices and secondly to a radio device, characterized in that a second test operating mode for testing the measurement recording device (3) is provided, in which the measurement recording device (3) is coupled firstly to the test device (1) for testing the radio devices and secondly to an essentially defined terminating impedance (10), with the measurement recording device (3) being tested by the test device (1) for testing radio devices.

2. The method as claimed in claim 1, characterized in that the impedance of the measurement recording device (3), preferably the real part (S11-real) of the impedance, is recorded as a function of the frequency by the test device (1) in order to test the measurement recording device (3).

3. The method as claimed in claim 1 or 2, characterized in that the test device (1) for testing radio devices has signal generator means (4) and receiving means (5) which are connected to one another via a single I/O connection (2), with the measurement recording device (3) being connected to the I/O connection (2), and with at least one signal which is produced by the signal generator means (4) in the second test operating mode being received by the receiving means (5) and then compared with at least one previously stored reference value.

4. The method as claimed in claim 3, characterized in that the receiving means (5) are provided for power measurement.

5. The method as claimed in claim 3 or 4, characterized in that the frequencies of the signal generator means (4) and of the receiving means (5) are tuned synchronously over a predetermined frequency range in the second test operating mode.

6. The method as claimed in claim 5, characterized in that the predetermined frequency range has at least one operating frequency range of a radio device.

7. The method as claimed in claim 5 or 6, characterized in that the frequency tuning is carried out in steps.

8. The method as claimed in one of claims 5 to 7, characterized in that the level of the signals which are produced by the signal generator means (4) is constant during the frequency tuning.

9. The method as claimed in one of claims 5 to 8, characterized in that a measurement curve, which is recorded over the frequency range, is compared with a reference curve.

10. The method as claimed in one of claims 3 to 9, characterized in that the signal generator means (4) and the receiving means (5) are connected to the I/O connection (2) via a Z/3 star (6).

11. The method as claimed in one of the preceding claims, characterized in that the second test mode is carried out intermittently with respect to the first test mode.

12. The method as claimed in one of the preceding claims, characterized in that the measurement recording device (3) comprises the terminating impedance.

13. The method as claimed in claim 12, characterized in that the terminating impedance is an antenna coupler (7).

14. The method as claimed in one of the preceding claims, characterized in that the radio devices are mobile telephones (10) which are intended to be operated in at least one mobile radio network.

15. The method as claimed in one of claims 1 to 10, characterized in that the terminating impedance (17) is a test radio device.

16. The method as claimed in claim 14, characterized in that the test radio device is an unequipped mobile telephone which has an equivalent impedance for a coaxial connection of the measurement recording device and a mobile telephone to be tested.

17. The method as claimed in claim 14 or 15, characterized in that the test radio device is fed two or more times into a production line, with means being provided in order to identify the test radio device as such and in order then to respond to this to initiate the second test operating mode.

18. The method as claimed in one of claims 3 to 15, characterized in that an alarm is triggered if a sufficient discrepancy is found between the reference curves and the signals recorded by the receiving means.

19. The method as claimed in one of claims 3 to 16, characterized in that the reference is stored in a memory device that is provided in the test device (1), or in an external appliance which is connected to it, for example a computer.

20. A test device (1) for testing radio devices, which is coupled to the radio devices via a measurement recording device (3) in a first test operating mode for testing radio devices, characterized in that the test device (1) has a second test operating mode for testing the measurement recording device (3), in which second test operating mode the measurement recording device (3) is coupled firstly to the test device (1) for testing the radio devices and secondly to an essentially defined terminating impedance, with the measurement recording device (3) being tested by the test device (1) for testing radio devices.

21. The test device (1) as claimed in claim 20, characterized in that the impedance of the measurement recording device (3), preferably the real part (S11 real) of the impedance, is recorded as a function of the frequency by the test device (1) in order to test the measurement recording device (3).

22. The test device (1) as claimed in claim 20 or 21, characterized in that the test device (1) for testing radio devices has signal generator means (4) and receiving means (5) which are connected to one another via a single I/O connection (2), with the measurement recording device (3) being connected to the I/O connection (2), and with at least one signal which is produced by the signal generator means (4) in the second test operating mode being received by the receiving means (5) and then compared with at least one previously stored reference value.

23. The test device (1) as claimed in claim 22, characterized in that the receiving means (5) are provided for power measurement.

24. The test device (1) as claimed in claim 22 or 23, characterized in that the frequencies of the signal generator means (4) and of the receiving means (5) are tuned synchronously over a predetermined frequency range in the second test operating mode.

25. The test device (1) as claimed in claim 24, characterized in that the predetermined frequency range has at least one operating frequency range of a radio device.

26. The test device (1) as claimed in claim 24 or 25, characterized in that the frequency tuning is carried out in steps.

27. The test device (1) as claimed in one of claims 24 to 26, characterized in that the level of the signals which are produced by the signal generator means (4) is constant during the frequency tuning.

28. The test device (1) as claimed in one of claims 24 to 27, characterized in that a measurement curve, which is recorded over the frequency range, is compared with a reference curve.

29. The test device (1) as claimed in one of claims 22 to 28, characterized in that the signal generator means (4) and the receiving means (5) are connected to the I/O connection (2) via a Z/3 star (6).

30. The test device (1) as claimed in one of the preceding claims 20 to 29, characterized in that the second test mode is carried out intermittently with respect to the first test mode.

31. The test device (1) as claimed in one of the preceding claims 20 to 30, characterized in that the measurement recording device (3) comprises the terminating impedance.

32. The test device (1) as claimed in claim 31, characterized in that the terminating impedance is an antenna coupler (7).

33. The test device (1) as claimed in one of the preceding claims 20 to 32, characterized in that the radio devices are mobile telephones (10) which are intended to be operated in at least one mobile radio network.

34. The test device (1) as claimed in one of claims 20 to 30, characterized in that the terminating impedance (17) is a test radio device.

35. The test device (1) as claimed in claim 33, characterized in that the test radio device is an unequipped mobile telephone which has an equivalent impedance for a coaxial connection of the measurement recording device and a mobile telephone to be tested.

36. The test device (1) as claimed in claim 33 or 34, characterized in that the test radio device is fed two or more times into a production line, with means being provided in order to identify the test radio device as such and in order then to respond to this to initiate the second test operating mode.

37. The test device (1) as claimed in one of claims 22 to 35, characterized in that an alarm is triggered if a sufficient discrepancy is found between the reference curves and the signals recorded by the receiving means.

38. The test device (1) as claimed in one of claims 22 to 36, characterized in that the reference is stored in a memory device that is provided in the test device (1), or in an external appliance which is connected to it, for example a computer.

39. Use of a test device (1) for testing radio devices for testing a measurement recording device (3), which is coupled to it, by means of an impedance measurement.
